(19) United States
(12) Patent Application Publication
(10) Pub. No.: US 2016/0285033 A1
(43) Pub. Date: Sep. 29, 2016

(54) ORGANIC LIGHT-EMITTING DISPLAY DEVICE

(71) Applicant: SAMSUNG DISPLAY CO., LTD., Yongin-si (KR)

(72) Inventor: Jaeho Lee, Yongin-si (KR)

(21) Appl. No.: 15/012,726

(22) Filed: Feb. 1, 2016

(30) Foreign Application Priority Data
Mar. 26, 2015 (KR) 10-2015-0042365

(51) Int. Cl. H01L 51/52; H01L 51/00; H01L 27/32

(52) U.S. Cl. CPC H01L 51/525; H01L 51/5275; H01L 27/3244; H01L 51/0094; H01L 51/004; H01L 2251/558

(57) ABSTRACT

An organic light-emitting display device includes a substrate; a display unit on the substrate and comprising a plurality of organic light-emitting diodes; a sealing member facing the substrate with the display unit between the sealing member and the substrate; and a filling member between the display unit and the sealing member and including a plurality of pores.

### CROSS-REFERENCE TO RELATED APPLICATION

This application claims priority to and the benefit of Korean Patent Application No. 10-2015-0042365, filed on Mar. 26, 2015, in the Korean Intellectual Property Office, the disclosure of which is incorporated herein in its entirety by reference.

### BACKGROUND

1. Field

One or more exemplary embodiments relate to an organic light-emitting display device.

2. Description of the Related Art

An organic light-emitting display device generally includes a hole injection electrode, an electron injection electrode, and an organic light-emitting diode that is disposed between the hole injection electrode and the electron injection electrode, and includes an organic emission layer. The organic light-emitting display device is a self-emitting display device in which light is generated when excitons (e.g., excitons that are generated when holes emitted from the hole injection electrode and electrons emitted from the electron injection electrode are combined in the organic emission layer) change from an excited state to a ground state.

Organic light-emitting display devices, which are self-emitting display devices, do not require an additional light source, and thus may be driven with a low voltage, and may be manufactured to be lightweight and thin. Also, the organic light-emitting display devices have high-quality characteristics, such as wide viewing angles, high contrast, and high response rates, and thus have drawn attention as next-generation display devices.

An organic light-emitting display device applied to a large TV, a monitor, etc. protects an organic light-emitting diode from external shock by using a filler therein. However, the filler may deteriorate the transmittance of light emitted from the organic light-emitting diode, and thus the filler is designed by taking into account a display quality as a display device.

### SUMMARY

An aspect of one or more exemplary embodiments include an organic light-emitting display device having enhanced emission efficiency and visibility while protecting a display device from external shock.

Additional aspects will be set forth in part in the description which follows and, in part, will be apparent from the description, or may be learned by practice of the presented embodiments.

According to an aspect of one or more exemplary embodiments, an organic light-emitting display device includes a substrate; a display unit on the substrate, and including a plurality of organic light-emitting diodes; a sealing member facing the substrate, the display unit being between the sealing member and the substrate; and a filling member between the display unit and the sealing member, and defining a plurality of pores.

The plurality of pores may be filled with an inert gas or are vacuous.

The inert gas may include at least one of nitrogen (N2) or argon (Ar).

A refractive index of the filling member may be greater than 1.3.

The filling member may include a permeable resin.

The permeable resin include at least one of a siloxane-based material and an acrylic-based material.

A thickness of the filling member may be less than 8 μm.

The plurality of organic light-emitting diodes may emit light toward the sealing member.

### BRIEF DESCRIPTION OF THE DRAWINGS

These and/or other aspects will become apparent and more readily appreciated from the following description of the exemplary embodiments, taken in conjunction with the accompanying drawings in which:

FIG. 1 is a schematic view of an organic light-emitting display device according to an exemplary embodiment;

FIG. 2 is a schematic cross-sectional view of the region X of the organic light-emitting display device of FIG. 1, showing a light travel path in the region X;

FIG. 3 is a schematic view of an organic light-emitting display device according to another exemplary embodiment;

FIGS. 4A and 4B are schematic cross-sectional views of the region Y of the organic light-emitting display device of FIG. 3, showing a light travel path in the region Y; and

FIG. 5 is a schematic cross-sectional view of a display unit of FIGS. 1 and 3.

### DETAILED DESCRIPTION

Reference will now be made in detail to exemplary embodiments, examples of which are illustrated in the accompanying drawings, wherein like reference numerals refer to like elements throughout. In this regard, the present exemplary embodiments may have different forms and should not be construed as being limited to the descriptions set forth herein. Accordingly, the exemplary embodiments are merely described below, by referring to the figures, to explain aspects of the present description. It would be obvious to those of ordinary skill in the art that exemplary embodiments are to cover all modifications, equivalents, and alternatives falling within the scope of the inventive concept. In the following description, well-known functions or constructions are not described in detail if it is determined that they would obscure the inventive concept due to unnecessary detail.

It will be understood that although the terms “first”, “second”, etc. may be used herein to describe various components, these components should not be limited by these terms. These terms are only used to distinguish one component from another.

It will be understood that when a layer, region, or component is referred to as being “formed on,” another layer, region, or component, it can be directly or indirectly formed on the other layer, region, or component. That is, for example, intervening layers, regions, or components may be present.

Hereinafter, exemplary embodiments will be described in detail with reference to the accompanying drawings. In the drawings, components that are substantially the same or that correspond to each other will be denoted by the same reference numeral and will not be redundantly described here. In the drawings, elements may be exaggerated, omitted, or schematically illustrated for convenience of explanation. In other words, since sizes and thicknesses of components in the drawings are arbitrarily illustrated for convenience of explanation, the following embodiments are not limited thereto. As used herein, the term “and/or” includes any and all combinations of one or more of the associated listed items. Expressions such as “at least one of,” when preceding a list of elements, modify the entire list of elements and do not modify the individual elements of the list.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that when an element or layer is referred to as being “on,” “connected to,” or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments only and is not intended to be limiting of the present invention. As used herein, the singular forms “a” and “an” are intended to include the plural forms as well, unless the context clearly indicates otherwise. It will be further understood that the terms “comprises,” “comprising,” “includes,” and “including,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

As used herein, the term “substantially,” “about,” and similar terms are used as terms of approximation and not as terms of degree, and are intended to account for the inherent deviations in measured or calculated values that would be recognized by those of ordinary skill in the art. Further, the use of “may” when describing embodiments of the present invention refers to “one or more embodiments of the present invention.” As used herein, the terms “use,” “using,” and “used” may be considered synonymous with the terms “utilize,” “utilizing,” and “utilized,” respectively. Also, the term “exemplary” is intended to refer to an example or illustration.

The electronic or electric devices and components and/or any other relevant devices or components according to embodiments of the present invention described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or the like. Further, the various components of these devices may be a process or thread, running on one or more processors, in one or more computing devices, executing computer program instructions and interacting with other system components for performing the various functionalities described herein. The computer program instructions may be stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of ordinary skill in the art should recognize that the functionality of various computing devices may be combined or integrated into a single computing device, or the functionality of a particular computing device may be distributed across one or more other computing devices without departing from the spirit and scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

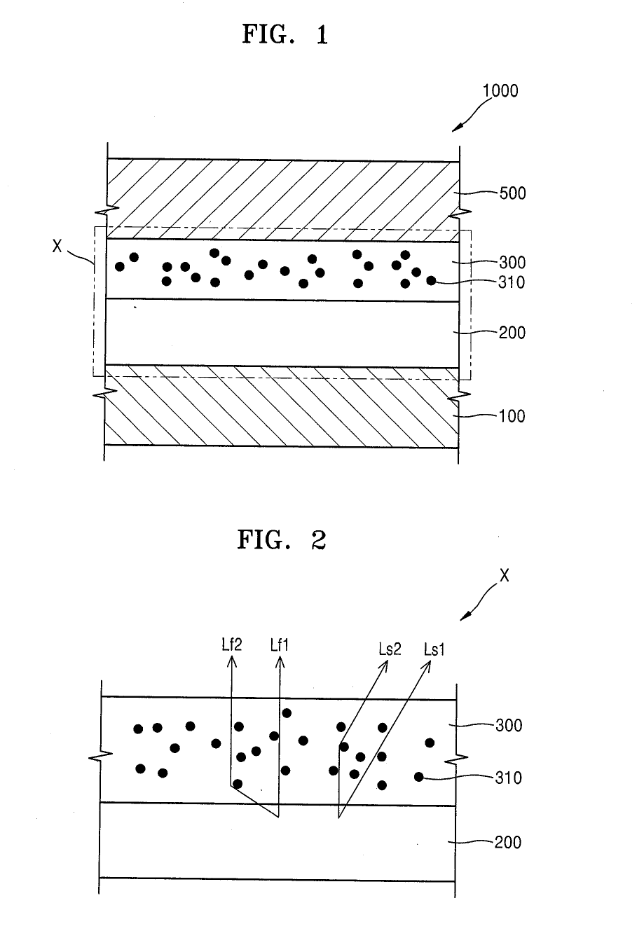

FIG. 1 is a schematic view of an organic light-emitting display device 1000 according to an exemplary embodiment. FIG. 2 is a schematic cross-sectional view of a light path in the region X of FIG. 1.

Referring to FIG. 1, the organic light-emitting display device 1000 according to an exemplary embodiment may include a substrate 100, a display unit 200 including a plurality of organic light-emitting diodes (OLEDs), a filling member 300, and a sealing member 500.

When the organic light-emitting display device 1000 is a bottom emission-type display device in which an image generated by the display unit 200 may be viewed from outside the organic light-emitting display device 1000 through the substrate 100, the substrate 100 may be formed of a transparent glass material having SiO₂ as a main component. However, the substrate 100 is not necessarily limited thereto. The substrate 100 may be formed of a transparent plastic material. The plastic material used to form the substrate 100 may be an insulating organic material selected from the group consisting of polyethersulphone (PES), polyacrylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (TAC), and cellulose acetate propionate (CAP).

According to an exemplary embodiment, when the organic light-emitting display device 1000 is a top emission-type display device in which an image is formed in a direction opposite to the substrate 100, the substrate 100 needs not be formed of a transparent material. For example, the substrate 100 may be formed of a metal.

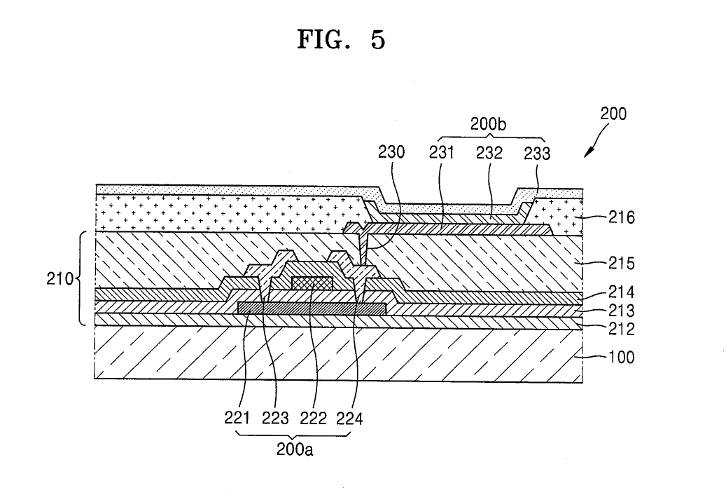

According to an embodiment, the display unit 200 is disposed on the substrate 100. The display unit 200 may include the plurality of OLEDs and a plurality of thin film transistors (TFTs) electrically connected to the plurality of OLEDs to provide an image recognizable by a user. A detailed description of the display unit 200 will be provided in detail with reference to FIG. 5 later.

According to an embodiment, the sealing member 500 is disposed on the display unit 200. The sealing member 500 is disposed facing the substrate 100 with the display unit between the sealing member 500 and the substrate 100. Similar to the substrate 100, the sealing member 500 may have a flat or substantially flat plate shape but may have a structure in which at least one or more insulating films are stacked.

When the sealing member 500 has a flat or substantially flat plate shape that is similar to that of the substrate 100 according to an exemplary embodiment, the sealing member 500 may be formed of the transparent glass or plastic material having SiO₂ as the main component, like the substrate 100. In some embodiments, the sealing member 500 is formed of a transparent material in a top emission-type display device, whereas the sealing member 500 is not necessarily formed of a transparent material in a bottom emission-type display device.

According to an embodiment, the sealing member 500 and the substrate 100 may be bonded to each other by a separate sealing member. For example, the separate sealing member may be disposed to surround the display unit 200 between the sealing member 500 and the substrate 100. A space between the sealing member 500 and the substrate 100 is sealed by the separate sealing member, thereby preventing external moisture, air, and other impurities from penetrating into the display unit 200 disposed in the space.

When the sealing member 500 has the structure in which at least one or more insulating films are stacked according to another exemplary embodiment, the sealing member 500 may include at least one or more organic films and/or at least one or more inorganic films. The sealing member 500 may have a structure in which the organic films and the inorganic films are alternately stacked. As described above, in some embodiments, at least one or more thin insulating films completely cover the display unit 200, thereby preventing external moisture, air, and other impurities from penetrating into the display unit 200, and providing a flexible characteristic to the display device.

According to an embodiment, the filling member 300 is disposed between the sealing member 500 and the display unit 200. The filling member 300 may include a plurality of pores, which will be described in detail with reference to FIG. 2 below.

FIG. 2 is a schematic cross-sectional view of the region X of the organic light-emitting display device 1000 of FIG. 1 (i.e., the display unit 200, and the filling member 300 disposed on the display unit 200), and showing a light travel path in the region X.

Referring to FIG. 2, a plurality of pores 310 may be irregularly distributed in the filling member 300, and may be charged with inert gas or may be vacuous. In this regard, the inert gas may be at least one of nitrogen (N₂) and/or argon (Ar) but is not necessarily limited thereto.

According to an embodiment, light generated by a display device of the display unit 200 may pass through the filling member 300. As shown in FIG. 2, the light travel path may be partially changed by the pores 310 distributed in the filling member 300. That is, an inclined light Lf2, which travels in an inclined direction with respect to one surface of the filling member 300, may be a front light that travels in the same direction as a perpendicular light Lf1 refracted by the pores 310 in the filling member 300, and traveling in a direction perpendicular to one surface of the filling member 300. Likewise, a perpendicular light Ls2, which travels in a direction approximately perpendicular to one surface of the filling member 300, may be a side light that travels in substantially the same direction as an inclined light Ls1 traveling in an inclined direction with respect to one surface of the filling member 300. Accordingly, light recognized by the user centered in front of the display device may be a mixture of the perpendicular light Lf1 and the inclined light Lf2, and light recognized by the user at an inclination angle with respect to an edge of the display device may also be a mixture of the perpendicular light Ls2 and the inclined light Ls1. Thus, the user may recognize a similarly mixed light irrespective of a viewing angle, thereby reducing a deviation of an optical characteristic according to the viewing angle and enhancing visibility. An example of the deviation of the optical characteristic according to the viewing angle may be a color difference according to the viewing angle, etc.

A refractive index of the filling member 300 may be different from refractive indexes of the pores 310 so as to reduce a color difference according to an angle as described above. That is, a medium characteristic of the filling member 300 may be different from medium characteristics of the pores 310 such that light passing through the filling member 300 may be incident into the pores 310 and refracted in a different direction. In this regard, if a difference in the refractive index between the filling member 300 and the pores 310 is too small (e.g., relatively too small), it may be difficult to effectively refract the light passing through the filling member 300. Thus, by taking into account that the refractive indexes of the pores 310 are about 1 in an inert gas or vacuum, the refractive index of the filling member 300 may be at least 1.3.

The filling member 300 may be formed of a foamed plastic material in which the pores 310 may be irregularly distributed. In this regard, the plastic material may include permeable resin to allow the light generated by the display device to easily transmit through the filling member 300. The permeable resin may have a refractive index of at least 1.3 and may include the transparent material as described above. For example, the permeable resin may include at least one of a siloxane-based material and an acrylic-based material.

In some embodiments, the filling member 300 is charged with the inert gas or the plurality of pores 310 in a vacuum are formed in the filling member 300, thereby preventing the display device from being contaminated with intentionally added impurities. That is, according to the embodiment, it is unnecessary to distribute separate additives in the filing member 300 to facilitate a refraction phenomenon of the light passing through the filling member 300, thereby preventing the organic light-emitting display device from deteriorating in the display unit 200 due to the additives. The pores 310 of the filling member 300 function as shock-absorbing materials for absorbing external shock, thereby minimizing damage caused to the organic light-emitting display device due to external shock.

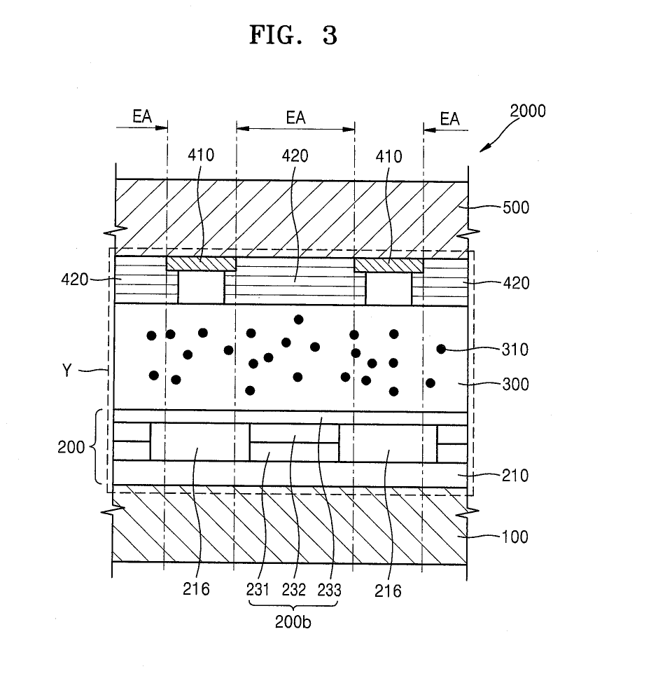

FIG. 3 is a schematic view of an organic light-emitting display device 2000 according to another exemplary embodiment.

Referring to FIG. 3, the organic light-emitting display device 2000 according to another exemplary embodiment may include the substrate 100, the display unit 200, the filling member 300, the sealing member 500, and a light block member (e.g., a light-blocking member) 410 disposed between the filling member 300 and the sealing member 500. Like reference numerals between FIGS. 3 and 1 refer to like elements. The like elements are substantially the same in function and/or operation, and thus redundant descriptions thereof are omitted below.

The display unit 200 may include a plurality of OLEDs 200b, each including a first electrode 231, a second electrode 233 facing the first electrode 231, and an intermediate layer 232 between the first electrode 231 and the second electrode 233. A pixel-defining film 216 may be disposed between every two adjacent OLEDs 200b. The OLEDs 200b and the pixel-defining film 216 will be described in detail with reference to FIG. 5 later.

The second electrode 233 of the OLEDs 200b may be formed of a reflective material over the entire substrate 100. Thus, light incident from outside of the organic light-emitting display device 2000 may be reflected by the second electrode 233, and may deteriorate the display quality of the organic light-emitting display device 2000. Thus the light block member 410 may be used to adjust a size of a region through which the second electrode 233 is exposed.

The light block member 410 may be disposed between the filling member 300 and the sealing member 500. The light block member 410 may include openings corresponding to the OLEDs 200b to define emission areas EA corresponding to the OLEDs 200b. That is, the openings of the light block member 410, or between adjacent light block members 410, may be used to emit the light generated by the OLEDs 200b to the outside of the organic light-emitting display device 2000.

The light block member 410 may be formed of various materials, for example, a black organic material that is a mixture of black pigments or chrome oxide (CrOₓ).

A method of manufacturing the light block member 410 may be different depending on materials used to form the light block member 410. For example, when the light block member 410 is formed of Cr or CrOₓ, sputtering or E-beam deposition may be used to form the light block member 410 in a single layer structure or in a multilayer structure.

In some embodiments, color filter members 420 may be disposed in the openings between the light block members 410. The color filter members 420 may be disposed corresponding to the emission areas EA, and may partially overlap with a part of the light block members 410. Thicknesses of the color filter members 420 are greater than those of the light block members 410 in FIG. 3, but are not necessarily limited thereto. The thicknesses of the color filter members 420 may be the same as those of the light block members 410.

The color filter member 420 may include a color forming material, and an organic material in which the color forming materials are distributed. The color forming material may be a pigment or dye. The organic material may be a dispersing agent.

According to an exemplary embodiment, when white light is generated by the OLEDs 200b, the color filter member 420 may selectively pass light of a specific wavelength, such as red, green, or blue, of the white light, and may absorb light of other wavelengths. Thus, red light, green light, and blue light may be emitted by the plurality of emission areas EA according to the color filter members 420 disposed corresponding to the emission areas EA.

According to another exemplary embodiment, when a visible ray having a predetermined color (e.g., a red, green, or blue visible ray) is generated by the OLEDs 200b, the color filter members 420 may enhance a light characteristic of the visible ray.

A method of manufacturing the color filter member 420 may include a pigment distribution method, a printing method, an electrodeposition method, a thermal transfer method, etc.

In some embodiments, an adhesive layer formed of SiO₂ or SiNₓ, may be formed between the light block member 410 and the sealing member 500, and between the color filter member 420 and the sealing member 500, so as to increase adhesion to the sealing member 500.

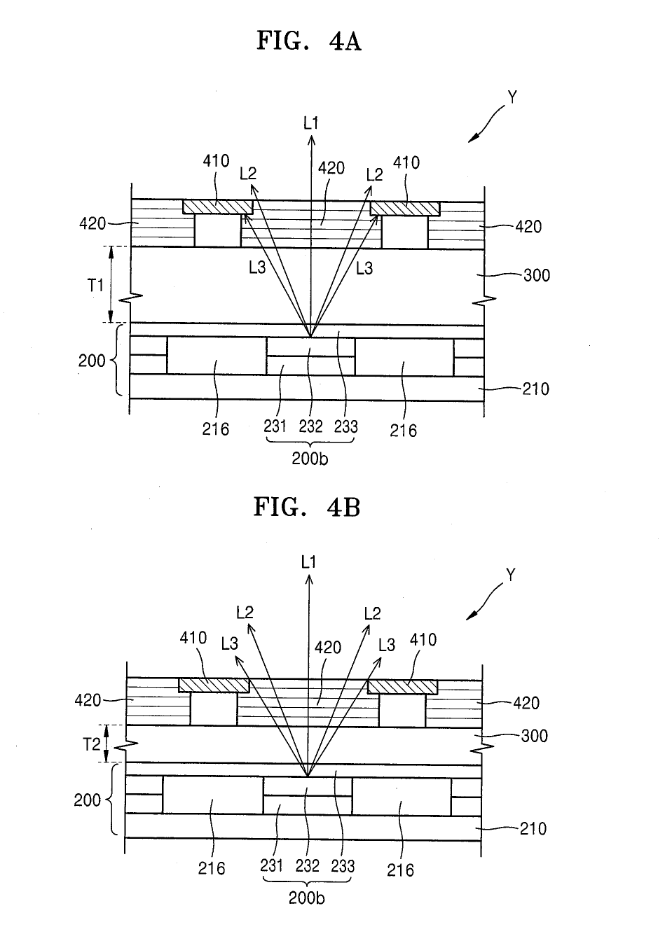

As described above, the light block member 410 is used to reduce the region through which the second electrode 233 is exposed, thereby preventing the display quality from deteriorating due to external light reflected from the second electrode 233. However, an extreme increase in the size of the light block member 410 may result in a reduction in the size of the emission regions EA, and thus the emission efficiency of the organic light-emitting display device 2000 may be reduced. A structure of the display device for solving this problem will now be described with reference to FIGS. 4A and 4B.

FIGS. 4A and 4B are schematic cross-sectional views of the region Y of the organic light-emitting display device of FIG. 3, showing a light path in the region Y.

Like reference numerals between FIGS. 4A and 4B and 1 refer to like elements. The like elements are substantially the same in function and/or operation, and thus redundant descriptions thereof are omitted below.

Referring to FIG. 4A, a first light L1 is light traveling in an approximately inclined direction with respect to one surface of the filling member 300, a second light L2 is light traveling in an inclined direction with respect to one surface of the filing member 300, and a third light L3 is light traveling in a direction that is more inclined than that of the second light L2 with respect to one surface of the filling member 300.

According to an embodiment with a thickness T1 of the filling member 300, the first light L1 and the second light L2 having a relatively small (e.g., smaller) spread with respect to a travel direction of the first light L1 may not be blocked by the light block member 410, and may pass through the color filter member 420 to be emitted to the outside. However, the third light L3 having a relatively larger spread with respect to the travel direction of the first light L1 may be blocked by the light block member 410, and might not be emitted to the outside.

Contrastingly, and referring to FIG. 4B, when the thickness T1 of the filling member 300, as shown in FIG. 4A, is reduced to a thickness T2, in addition to the first light L1 and the second light L2, the third light L3 having the relatively larger spread with respect to the travel direction of the first light L1 might also be not blocked by the light block member 410, and may pass through the color filter member 420 to be emitted to the outside. That is, a gap (e.g., the distance) between the light block member 410 and the OLEDs 200b is reduced by forming the filling member 300 having a small thickness (e.g., a relatively thinner filling member 300), thereby increasing emission efficiency without changing a size and a location of the light block member 410.

Therefore, instead of increasing an emission region by reducing the size of the light block member 410, the display device having enhanced emission efficiency may be obtained by forming a filling member 300 having a relatively small thickness. The light block member 410 of a sufficient or suitable size may be secured, thereby reducing or minimizing the exposed region of the second electrode 233 that reflects external light.

For example, when the thickness of the filling member 300 is greater than 8 μm, the deterioration of the emission efficiency of the organic light-emitting display device 2000 due to a light loss may be problematic. Thus, the thickness of the filling member 300 may be less than 8 μm.

FIG. 5 is a schematic cross-sectional view of the display unit 200 of FIGS. 1 and 3.

Referring to FIG. 5, a buffer layer 212 may be formed on the substrate 100. The buffer layer 212 may prevent impure elements from permeating the substrate 100, may provide a flat or substantially flat surface on the substrate 100, and may be formed of various materials capable of performing such functions. For example, the buffer layer 212 may include inorganic materials such as silicon oxide (SiOx), silicon nitride (SiNx), silicon oxynitride (SiOxNy), aluminum oxide, aluminum nitride, titanium oxide, titanium nitride, etc., or organic materials such as polyimide, polyester, acryl, etc., and may have a stack structure in which the above materials are stacked.

An active layer 221 may be formed on the buffer layer 212 of an inorganic semiconductor material, such as silicon or an organic semiconductor material. The active layer 221 may include a source region, a drain region, and a channel region between the source region and drain region. For example, when amorphous silicon is used to form the active layer 221, the active layer 221 including the source region, the drain region, and the channel region between the source region and drain region may be formed by forming and crystallizing an amorphous silicon layer on an entire surface of the substrate 100, forming a polycrystalline silicon layer, patterning the polycrystalline silicon layer, and respectively doping a source region and a drain region at respective edges of the polycrystalline silicon layer with impurities.

A gate insulating film 213 may be formed on the active layer 221. The gate insulating film 213 may be used to insulate the active layer 221 from a gate electrode 222. The gate insulating film 213 may be formed of an inorganic material such as SiNx, SiO2, etc.

The gate electrode 222 may be formed on the gate insulating film 213. The gate electrode 222 may be connected to a gate line via which an on/off signal is supplied to a TFT.

The gate electrode 222 may contain gold (Au), silver (Ag), copper (Cu), nickel (Ni), platinum (Pt), palladium (Pd), aluminum (Al), and/or molybdenum (Mo), and may include an alloy such as an Al:Nd alloy, an Mo:W alloy, etc. but is not limited thereto. The gate electrode 222 may be formed of various materials by taking into account design conditions.

An interlayer insulating film 214, formed on the gate electrode 222, may be used to insulate the gate electrode 222, a source electrode 223, and a drain electrode 224 from one another. The interlayer insulating film 214 may be formed of an inorganic material such as SiNx, SiO2, etc.

The source electrode 223 and the drain electrode 224 may be formed on the interlayer insulating film 214. In more detail, the interlayer insulating film 214 and the gate insulating film 213 may expose parts of the source region and the drain region of the active layer 221, and the source electrode 223 and the drain electrode 224 may respectively contact the exposed parts of the source region and the drain region of the active layer 221.

A top gate type TFT, in which the gate electrode 222, the source electrode 223, and the drain electrode 24 are sequentially formed, is illustrated in FIG. 5, but the exemplary embodiments are not limited thereto. The gate electrode 222 may be disposed below the active layer 221.

A TFT 200a may be electrically connected to the OLEDs 200b to drive the OLEDs 200b, and may be protected by being covered by a planarizing film 215.

The planarizing film 215 may include an inorganic insulating material and/or an organic insulting material. The inorganic insulating material may include SiO₂, SiNₓ, SiON, Al₂O₃, TiO₂, Ta₂O₅, HfO₂, ZrO₂, BST, and/or PZT. The organic insulting material may include a general-purpose polymer, such as polymethyl methacrylate (PMMA) or polystyrene (PS), a polymeric derivative having a phenol-based group, an acryl-based polymer, an imide-based polymer, an arylether-based polymer, an amide-based polymer, a fluorine-based polymer, a p-xylene-based polymer, a vinyl alcohol-based polymer, and/or a mixture thereof. The planarizing film 215 may be formed as a composite stack structure including the inorganic insulating film and the organic insulating film.

The OLEDs 200b may include the first electrode 231, the intermediate layer 232, and the second electrode 233.

The first electrode 231 may be formed on the planarizing film 215 and may be electrically connected to the drain electrode 224 through a contact hole 230 formed in the planarizing film 215, but is not necessarily limited thereto. For example, the first electrode 231 may be electrically connected to the source electrode 223 instead.

The first electrode 231 may be a reflective electrode and may include a reflective film formed of Ag, Mg, Al, Pt, Pd, Au, Ni, Nd, Ir, Cr, or a combination thereof, and may further include a transparent or semi-transparent electrode layer formed on the reflective film. The transparent or semi-transparent electrode layer may include at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO).

The second electrode 233 facing the first electrode 231 may be a transparent or semi-transparent electrode, and may be formed of a metal thin film with a low work function such as Li, Ca, LiF/Ca, LiF/AI, Al, Ag, Mg, or a combination thereof. As another example, an auxiliary electrode layer or a bus electrode may be further formed on the metal thin film by using a material for forming a transparent electrode, e.g., ITO, IZO, ZnO, In₂O₃, and/or the like. The second electrode 233 may be formed over the entire substrate 100 and may be formed of a material having a predetermined reflectivity.

Thus, the second electrode 233 may allow light emitted from an organic emission layer included in the intermediate layer 232 to pass through in a direction toward the sealing member 500 of FIGS. 1 and 3. That is, the light emitted from the organic emission layer may be reflected directly or via the first electrode 231, which is a reflective electrode, and may be emitted toward the second electrode 233.

However, the organic light-emitting display device of the present embodiment is not limited to a top emission-type display device, and may instead be a bottom emission-type display device in which the light emitted from the organic emission layer is emitted toward the substrate 100. In this case, the first electrode 231 may be a transparent or semi-transparent electrode, and the second electrode 233 may be a reflective electrode. The organic light-emitting display device of the present embodiment may also be a dual emission-type display device in which light is emitted in both directions of front and bottom surfaces thereof.

A pixel-defining film 216 is formed on the first electrode 231. The pixel-defining film 216 may be formed of at least one organic insulating material selected from the group consisting of polyimide, polyamide, acryl resin, benzocyclobutene, and phenol resin by spin coating or the like. The pixel-defining film 216 may expose a region of the first electrode 231, and the intermediate layer 232 with the organic emission layer may be located on the exposed region of the first electrode 231.

The organic emission layer included in the intermediate layer 232 may include a low molecular weight organic material or a high molecular weight organic material. The intermediate layer 232 may selectively further include a functional layer, such as a hole transport layer (HTL), a hole injection layer (HIL), an electron transport layer (ETL), an electron injection layer (EIL), etc.

The cross-sectional view of FIG. 5 is exemplary, and a structure of the display unit 200 according to the exemplary embodiments may be modified in various ways according to other embodiments.

As described above, according to the one or more of the above exemplary embodiments, an organic light-emitting display device may prevent an OLED from being damaged by external shock.

According to the one or more of the above exemplary embodiments, an organic light-emitting display device may reduce a color difference caused by a viewing angle.

According to the one or more of the above exemplary embodiments, an organic light-emitting display device may prevent an OLED from deteriorating by an additive added therein.

According to the one or more of the above exemplary embodiments, an organic light-emitting display device may reduce a thickness of a panel, thereby implementing a lightweight display device having enhanced emission efficiency.

It should be understood that exemplary embodiments described herein should be considered in a descriptive sense only and not for purposes of limitation. Descriptions of features or aspects within each exemplary embodiment should typically be considered as available for other similar features or aspects in other exemplary embodiments.

While one or more exemplary embodiments have been described with reference to the figures, it will be understood by those of ordinary skill in the art that various changes in form and details may be made therein without departing from the spirit and scope as defined by the following claims, and their equivalents.

What is claimed is:

1. An organic light-emitting display device comprising:
a substrate;
a display unit on the substrate, and comprising a plurality of organic light-emitting diodes;
a sealing member facing the substrate, the display unit being between the sealing member and the substrate; and
a filling member between the display unit and the sealing member, and defining a plurality of pores.

2. The organic light-emitting display device of claim 1, wherein the plurality of pores are filled with an inert gas or are vacuous.

3. The organic light-emitting display device of claim 2, wherein the inert gas comprises at least one of nitrogen (N2) or argon (Ar).

4. The organic light-emitting display device of claim 1, wherein a refractive index of the filling member is greater than 1.3.

5. The organic light-emitting display device of claim 1, wherein the filling member comprises a permeable resin.

6. The organic light-emitting display device of claim 5, wherein the permeable resin comprises at least one of a siloxane-based material and an acrylic-based material.

7. The organic light-emitting display device of claim 1, wherein a thickness of the filling member is less than 8 μm.

8. The organic light-emitting display device of claim 1, wherein the plurality of organic light-emitting diodes emit light toward the sealing member.
